(19) United States
(12) Patent Application Publication
(10) Pub. No.: US 2013/0049119 A1
(43) Pub. Date: Feb. 28, 2013

(54) MULTI-WORKING VOLTAGES CMOS DEVICE WITH SINGLE GATE OXIDE LAYER THICKNESS AND MANUFACTURING METHOD THEREOF

(71) Applicants: Xiaolu HUANG, Shanghai (CN); Gang MAO, Shanghai (CN); Yuwen CHEN, Shanghai (CN); Xinyun XIE, Shanghai (CN)

(72) Inventors: Xiaolu HUANG, Shanghai (CN); Gang MAO, Shanghai (CN); Yuwen CHEN, Shanghai (CN); Xinyun XIE, Shanghai (CN)

(73) Assignee: SHANGHAI HUALI MICROELECTRONICS CORPORATION, Shanghai (CN)

(21) Appl. No.: 13/339,438

(22) Filed: Dec. 29, 2011

(30) Foreign Application Priority Data
Aug. 29, 2011 (CN) 201110250267.2
Sep. 8, 2011 (CN) 201110265327.8

(51) Int. Cl. H01L 27/092; H01L 27/12; H01L 21/86; H01L 21/8238

(52) U.S. Cl. 257/351; 257/369; 438/221; 438/154; 257/E27.062; 257/E27.112; 257/E21.632; 257/E21.704

(57) ABSTRACT

The present invention provides a multi-working voltages CMOS device with single gate oxide layer thickness, gate work functions of CMOS transistors are regulated by implanting ions with different work functions into metal oxide dielectric material layers of the CMOS transistors, thus to realize different flat-band voltages under the condition of single dielectric layer thickness, and realize a multi-working voltages CMOS structure under the condition of single dielectric layer thickness. The present invention overcomes the process complexity of multiple kinds of gate dielectric layer thicknesses needed by traditional multi-working voltages CMOS, simplifies the CMOS process, makes the manufacturing procedure simple and easy to execute, reduces the preparation cost and is suitable for industrial production.

### CROSS REFERENCE TO RELATED APPLICATIONS

The present application is based upon and claims priority under 35 U.S.C. §119 to prior Chinese Patent Application No. 201110265327.8 filed on Sep. 8, 2011 and prior Chinese Patent Application No. 201110250267.2 filed on Aug. 29, 2011, the entire contents of which are incorporated herein by reference.

### FIELD OF THE INVENTION

The present invention relates to a manufacturing method of an integrated circuit, and particularly to a multi-working voltages CMOS device with single gate oxide (GOX) layer thickness and a manufacturing method thereof, and a multi-working voltages gate-last process semiconductor device with single gate oxide layer thickness and a manufacturing method thereof.

### BACKGROUND OF THE INVENTION

In logic circuits or memory circuits of semiconductors, multi-working voltages are adopted in many CMOS (Complementary Metal-Oxide-Semiconductors) because of requirements for circuit design.

For example, working voltages for core circuits generally use low working voltage, such as 1.0V, 1.2V, 1.5V etc., and working voltages for peripheral circuit generally use high working voltage, such as 1.8V, 2.5V, 3.3V etc. CMOS in the core circuits are generally called as Core NMOS or Core PMOS, and CMOS in the peripheral circuits are generally called as IO NMOS or IO PMOS.

For Core and IO MOS devices, traditional manufacturing methods of devices use different gate dielectric layer thicknesses to change threshold voltages of various devices, so as to change their working voltages. For example, Core MOS devices generally use relatively thin gate dielectric layer thickness, which have relatively low threshold voltages; and IO MOS devices generally use relatively thick gate dielectric layer thickness, which have relatively high threshold voltages.

Therefore, in a traditional manufacturing process of logic circuits or memory circuits, such as in a generally used dual gate oxide process shown in FIG. 1 (a), the thickness of a gate dielectric layer a1 in a MOS transistor A1 is smaller than the thickness of a gate dielectric layer a2 in a MOS transistor A2, thereby to regulate the threshold voltages of MOS transistors A1 and A2, so that the MOS device realizes dual working voltages. Sometimes, transistors even use triple gate oxide process according to the demand for circuit design. As shown in FIG. 1(b), in MOS transistors B1, B2 and B3, the thicknesses of gate dielectric layers b1, b2 and b3 are different from each other, which makes threshold voltages of MOS transistors B1, B2 and B3 different from each other, so as to realize triple working voltages.

However, in the above method which changes the gate dielectric layer thicknesses of the MOS transistors to regulate threshold voltages of the MOS transistors so as to realize multi-working voltages of the semiconductor device, the preparing processes of the semiconductor device are complex, which include processes of deposition and etching of gate dielectric layer for multiple times; further, it is difficult to realize the preparing processes, and preparing cost of the semiconductor device is increased.

Therefore, it is necessary to provide a new method for manufacturing a multi-working voltages CMOS structure with single gate oxide layer thickness.

### SUMMARY OF THE INVENTION

The first embodiment of the present invention provides a multi-working voltages CMOS device with single gate oxide layer thickness and a manufacturing method thereof. The present invention regulates work functions of CMOS transistors by CMOS transistor ion implanting, to realize different flat-band voltages under the condition of single dielectric layer thickness, thus to realize multi-working voltages CMOS structure with single dielectric layer thickness, so as to overcome the defects due to multiple kinds of gate dielectric layer thicknesses needed by the prior multi-working voltages CMOS, such as process complexity and high cost for preparation, and so on.

In the actual operation procedure of the MOS device, the working voltage of the MOS device is influenced by the work function of the MOS device directly. Taking the enhanced NMOS as an example, because the work function of the gate oxide layer in the NMOS transistors and that of the P-type semiconductor layer are not identical, the conduction band Ec and valence band Ev of the semiconductor layer which is near to the edge of the dielectric layer would be bent when MIS (metal-insulator-semiconductor) system is in balance state. When the device is in operation, a part of the voltage applied on the gate is used to suppress the bending of the conduction band Ec and valence band Ev, and this part of voltage is called as flat-band voltage. The flat-band voltage is a part of the working voltage in actual operation, and the change of the flat-band voltage changes the working voltage of the NMOS device directly, as shown in FIG. 2.

Also, as shown in FIG. 3, the magnitude of the flat-band voltage of a MOS device is influenced and changed by the gate work function qφₘ of the MOS device directly. Thus, different flat-band voltages can be formed under the condition of single dielectric layer thickness if changing the work function of the single-thickness dielectric layer of the MOS device, so the working voltages needed by the different flat-band voltages MOS devices are different from each other, thus to realize multi-working voltages CMOS structure with single dielectric layer thickness.

The multi-working voltages CMOS device with single gate oxide layer thickness and the manufacturing method thereof according to the first embodiment of the present invention realize the purposes by the following technical solutions.

A multi-working voltages CMOS device with single gate oxide layer thickness, wherein,

the CMOS device comprises a plurality of N-type MOS transistors and P-type MOS transistors, a gate of each of the N-type MOS transistors and the P-type MOS transistors comprises a high-k dielectric layer and a metal oxide dielectric material layer thereon, the thicknesses of the high-k dielectric layers are the same, and the thicknesses of the metal oxide dielectric material layers are the same,

wherein, the N-type MOS transistors and the P-type MOS transistors have different gate work functions by implanting different amount of ions, which change the work functions of the metal oxide dielectric material layers, into the metal oxide dielectric material layers of the N-type MOS transistors and the P-type MOS transistors, thus to realize a multi-working voltages CMOS structure under the condition of single dielectric layer thickness; and

there are at least two of the P-type MOS transistors with different gate work functions thus to have different working voltages, and there are at least two of the N-type MOS transistors with different gate work functions thus to have different working voltages.

In the above CMOS device, the gate work functions of the P-type MOS transistors are decreased and absolute values of the working voltages of the P-type MOS transistors are increased by implanting different amount of ions, which decrease the gate work functions of P-type MOS transistors, into the metal oxide dielectric material layers of the P-type MOS transistors; and

the gate work functions of the N-type MOS transistors are increased and the working voltages of the N-type MOS transistors are increased by implanting different amount of ions, which increase the gate work functions of N-type MOS transistors, into the metal oxide dielectric material layers of the N-type MOS transistors.

In the above CMOS devices, alternatively, a thin oxide layer is disposed below the high-k dielectric layer of each of the MOS transistors.

A method for preparing the multi-working voltages CMOS device with single gate oxide layer thickness as aforesaid, wherein, the preparing of the CMOS device comprises the following steps:

Step 1, establishing a plurality of N-type MOS transistor preparing regions and a plurality of P-type MOS transistor preparing regions on a substrate; and completing the preparation of shallow trenches and shallow trench isolation regions of a plurality of transistors;

Step 2, depositing a high-k dielectric layer and a metal oxide dielectric material layer on the N-type MOS transistor preparing regions and the P-type MOS transistor preparing regions of the substrate, the metal oxide dielectric material layer covering the high-k dielectric layer;

Step 3, implanting ions, which change work functions of the metal oxide dielectric material layer, into the metal oxide dielectric material layer of the MOS transistor preparing regions respectively by photolithographic process, thus to regulate gate work functions of the completed N-type MOS transistors and P-type MOS transistors, and realize a multi-working voltages CMOS structure under the condition of single dielectric layer thickness,

wherein, implanting different amount of ions, which can decrease the work functions of the metal oxide dielectric material layer, into the metal oxide dielectric material layer on the P-type MOS transistor preparing regions, thus to determine the gate work functions of the P-type MOS transistors in the multi-working voltages CMOS completed in a subsequent preparation; the specific steps are:
a. covering a photoresist layer on the metal oxide dielectric material layer on the N-type MOS transistor preparing regions by photolithographic process; and implanting ions, which decrease the work functions of the metal oxide dielectric material layer, into the metal oxide dielectric material layer on the P-type MOS transistor preparing regions, thus to decrease the work functions of the metal oxide dielectric material layer on the P-type MOS transistor preparing regions, so as to determine the gate work functions of the P-type MOS transistors in a first stage working voltage CMOS completed in the subsequent preparation; and then removing the photoresist layer;
b. covering a photoresist layer on the metal oxide dielectric material layer on the P-type MOS transistor preparing regions and the N-type MOS transistor preparing regions, performing photolithography, and removing the photoresist layer covered on part of the P-type MOS transistor preparing regions, wherein, the photoresist layer at least covers the metal oxide dielectric material layer on one P-type MOS transistor preparing region; further implanting ions, which decrease the work functions of the metal oxide dielectric material layer, into the metal oxide dielectric material layer on part of the P-type MOS transistor preparing regions exposed out of the photoresist layer, thus to further decrease the work functions of the metal oxide dielectric material layer, so as to determine the gate work functions of the P-type MOS transistors in a second stage working voltage CMOS completed in the subsequent preparation; and
c. analogically, repeating the step b, further successively implanting different amount of ions, which can decrease the work functions of the metal oxide dielectric material layer, into the metal oxide dielectric material layer on different P-type MOS transistor preparing regions which have been ion-implanted, so as to change the work functions of the metal oxide dielectric material layer on the P-type MOS transistor preparing regions, thus to determine the gate work functions of the P-type MOS transistors in a third stage or more stage working voltage CMOS completed in the subsequent preparation;
   completing the ion implanting into the metal oxide dielectric material layer on each of the P-type MOS transistor preparing regions, and determining the preparing regions of the P-type MOS transistors for each stage in the multi-working voltage CMOS, wherein, there are at least two P-type MOS transistor preparing regions, the work functions of the metal oxide dielectric material layer on the at least two P-type MOS transistor preparing regions being different from each other;

using a method which is the same as the method of implanting different amount of ions, which can decrease the work functions of the metal oxide dielectric material layer, into the metal oxide dielectric material layer on the P-type MOS transistor preparing regions, implanting different amount of ions, which can increase the work functions of the metal oxide dielectric material layer, into the metal oxide dielectric material layer on the N-type MOS transistor preparing regions, thus to determine the gate work functions of the N-type MOS transistors for each stage in the multi-working voltages CMOS completed in the subsequent preparation, and to determine the preparing regions of the N-type MOS transistors for each stage in the multi-working voltages CMOS; and there are at least two N-type MOS transistor preparing regions, the work functions of the metal oxide dielectric material layer on the at least two N-type MOS transistor preparing regions being different from each other; and

Step 4, removing the photoresist layer, and completing the subsequent preparation of the N-type MOS transistors and the P-type MOS transistors.

In the above method, the substrate is a bulk silicon or a silicon on insulator.

In the above methods, in the Step 1, alternatively, depositing a thin oxide layer on the substrate before the forming of the high-k dielectric layer, and the thin oxide layer being disposed below the high-k dielectric layer.

In the above CMOS device, the ions implanted into the metal oxide dielectric material layer on the P-type MOS transistors include the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element.

In the above CMOS device, the ions implanted into the metal oxide dielectric material layer on the N-type MOS transistors include the ions based on B, C, Al, Ti, Cr, Ni, Ge, As, Se, Rh, Pd, Te, Re, Pt, Au, Hg or Po element.

The advantages of using the multi-working voltages CMOS device with single gate oxide layer thickness and the preparing method thereof according to the first embodiment of the present invention are:

The multi-working voltages CMOS device with single gate oxide layer thickness of the present invention regulates a gate work function of CMOS transistors by implanting ions with different work functions into a metal oxide dielectric material layer of the CMOS transistors, to realize different flat-band voltages under the condition of single dielectric layer thickness, and to realize multi-working voltages CMOS structure under the condition of single dielectric layer thickness. The manufacturing process of the present invention is simple and easy to execute, has a low preparation cost, and is suitable for industrial production. Although the first embodiment of the present invention takes gate-first CMOS (Gate-first HK/MG CMOS) preparing process as an example, the present invention is also suitable for gate-last CMOS (Gate-last HK/MG CMOS) preparing process.

The purpose of the second embodiment of the present invention is to provide a multi-working voltage CMOS structure and a manufacturing method thereof, the manufacturing process of which is simple and the cost of which is relatively low.

In order to overcome the defects of the prior art, the second embodiment of the present invention discloses a multi-working voltages gate-last process semiconductor device with single gate oxide layer thickness, including:

a plurality of first type transistors formed on a substrate, each of the first type transistors respectively corresponding to a second type transistor which has an absolute value of a flat-band voltage similar to that of the first type transistor;

gate trenches, included in the plurality of first type transistors and the plurality of second type transistors respectively;

gate oxide layers, formed on the bottom of the respective gate trenches of the plurality of first type transistors and the plurality of second type transistors, the thicknesses of each of the gate oxide layers being the same, wherein,

the gate oxide layers of the plurality of first type transistors are implanted with different amount of first ions respectively, such that flat-band voltages of at least two first type transistors are different from each other; and

the gate oxide layers of the plurality of second type transistors are implanted with different amount of second ions respectively, such that flat-band voltages of at least two second type transistors are different from each other.

In the above device, the substrate is a bulk silicon or a silicon on insulator.

In the above device, the first type transistors are PMOS transistors, the second type transistors are NMOS transistors, and the semiconductor device is a CMOS device.

In the above device, the semiconductor device includes:

at least a pair of first CMOS devices, the gate oxide layers of the PMOS transistors of the first CMOS devices have a first flat-band voltage by implanting first fixed quantity first ions, and the gate oxide layers of the NMOS transistors of the first CMOS devices have the first flat-band voltage by implanting second fixed quantity second ions; and

at least a pair of second CMOS devices, the gate oxide layers of the PMOS transistors of the second CMOS devices have a second flat-band voltage by implanting the first ions which have a quantity different from the first fixed quantity, the gate oxide layers of the NMOS transistors of the second CMOS devices have the second flat-band voltage by implanting the second ions which have a quantity different from the second fixed quantity.

In the above device, the first ions are ions having relatively small work functions, and the second ions are ions having relatively large work functions. In the above device, the first ions are any of the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element.

In the above device, the second ions are any of the ions based on B, C, Al, Ti, Cr, Ni, Ge, As, Se, Rh, Pd, Te, Re, Pt, Au, Hg or Po element.

According to another aspect of the second embodiment of the present invention, there is also disclosed a method for preparing a multi-working voltages gate-last process semiconductor device with single gate oxide layer thickness, which is used for a gate-last preparing process, comprising steps of:

firstly, forming a plurality of first type transistors and a plurality of second type transistors on a substrate, and forming gate trenches included in the plurality of first type transistors and the plurality of second type transistors respectively; then, the following steps are performed subsequently:

depositing a gate oxide layer in gate trenches of each of the first type transistors and the second type transistors, the thicknesses of each of the gate oxide layers being the same;

implanting first ions into the gate oxide layers of the first type transistors for multiple times, each implanting at least opening a gate trench of one of the first type transistors, such that the first ions contact the gate oxide layers in the opened gate trenches, so as to obtain at least two first type transistors having different flat-band voltages;

implanting second ions into the gate oxide layers of the second type transistors for multiple times, each implanting at least opening a gate trench of one of the second type transistors, such that the second ions contact the gate oxide layers in the opened gate trenches, so as to obtain at least two second type transistors having different flat-band voltages, and such that a flat-band voltage absolute value of each second type transistor is similar to that of a corresponding first type transistor.

In the above method, the step of implanting first ions into the gate oxide layers of the first type transistors for multiple times includes:

covering a photoresist layer as an implanting barrier layer on the first type transistors and the second type transistors;

removing part of the implanting barrier layer on the first type transistors by photolithographic process;

implanting first ions into the gate oxide layers in the gate trenches of the first type transistors;

covering another photoresist layer as an implanting barrier layer on the first type transistors and the second type transistors;

removing part of the implanting barrier layer on at least one first type transistor by photolithographic process, to open the gate trench of the at least one first type transistor, such that the gate oxide layer in the gate trench of the opened first type transistor is exposed, and remaining part of the implanting barrier layer covered on the second type transistors and other first type transistors;

implanting the first ions into the exposed gate oxide layer; repeating the aforesaid implanting procedure of the first ions until at least two first type transistors having different flat-band voltages of the gate oxide layers are formed; and

removing the implanting barrier layer, such that the first type transistors and second type transistors are exposed.

In the above method, the step of implanting second ions into the gate oxide layers of the second type transistors for multiple times includes: covering a photoresist layer as an implanting barrier layer on the first type transistors and the second type transistors;

removing part of the implanting barrier layer on the second type transistors by photolithographic process;

implanting second ions into the gate oxide layers in the gate trenches of the second type transistors;

covering another photoresist layer as an implanting barrier layer on the first type transistors and the second type transistors;

removing part of the implanting barrier layer on at least one second type transistor by photolithographic process, to open the gate trench of the at least one second type transistor, such that the gate oxide layer in the gate trench of the opened second type transistor is exposed, and remaining part of the

implanting barrier layer covered on the first type transistors and other second type transistors;

implanting the second ions into the exposed gate oxide layer;

repeating the aforesaid implanting procedure of the second ions until at least two second type transistors having different flat-band voltages of the gate oxide layers are formed; and

removing the implanting barrier layer, such that the first type transistors and second type transistors are exposed.

In the above method, the first type transistors are PMOS transistors, the second type transistors are NMOS transistors, and the semiconductor device is a CMOS device.

In the above method, the first ions are ions having relatively small work functions, the second ions are ions having relatively large work functions.

In the above method, the substrate is a bulk silicon or a silicon on insulator.

In the above method, the first ions are any of the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element.

In the above method, the second ions are any of the ions based on B, C, Al, Ti, Cr, Ni, Ge, As, Se, Rh, Pd, Te, Re, Pt, Au, Hg or Po element. The second embodiment of the present invention regulates the work function by ion implanting into a single-thickness gate dielectric layer, and realizes different flat-band voltages under the condition of single dielectric layer thickness, thus to realize multi-working voltages CMOS structure under the condition of single dielectric layer thickness. The second embodiment of the present invention overcomes the process complexity of multiple kinds of gate dielectric layer thicknesses needed by the traditional multi-working voltages CMOS, makes the CMOS manufacturing process simplified, and reduces the cost. The second embodiment of the present invention is also suitable for Gate-last HK/MG CMOS process.

### DESCRIPTION OF THE DRAWINGS

The present invention and its features, outlines and advantages will be more apparent by reading the detailed description to unlimited embodiments with reference to the accompanying drawings. In all of the drawings, like numerals denote like elements. The drawings are not drawn to scale deliberately, and the key point of the drawings is to show the subject matter of the present invention. In the drawings, a part of components are enlarged for clarity.

FIG. 1 is a schematic diagram of Multi-working voltages CMOS structure of prior art;

FIG. 1(a) is a schematic diagram of dual-working voltage CMOS structure with dual gate oxide progress;

FIG. 1(b) is a schematic diagram of triple working voltage CMOS structure with triple gate oxide progress;

FIG. 2 is a principle diagram for creating flat-band voltage in the operation of NMOS;

FIG. 3 is a principle diagram of different flat-band voltage MIS energy band with different work functions;

FIG. 4 is a structural schematic diagram of dual working voltage CMOS device with single gate oxide layer thickness according to a first embodiment of the present invention;

FIG. 5 is a structural schematic diagram of a semiconductor substrate covered with a metal oxide dielectric material layer, a high-k dielectric layer and a thin oxide layer in the first embodiment of the present invention;

FIG. 6 is a schematic diagram of implanting ions into the metal oxide dielectric material layer on PMOS in the first embodiment of the present invention;

FIG. 7 is a schematic diagram of further implanting ions into the metal oxide dielectric material layer on part of the PMOS in the first embodiment of the present invention;

FIG. 8 is a schematic diagram of implanting ions into the metal oxide dielectric material layer on NMOS in the first embodiment of the present invention;

FIG. 9 is a schematic diagram of further implanting ions into the metal oxide dielectric material layer on part of the NMOS in the first embodiment of the present invention;

FIG. 10 is a schematic diagram of Multi-working voltages gate-last CMOS structure with single gate oxide layer thickness in a second embodiment of the present invention; and

FIG. 11 to FIG. 14 are flow charts of preparing method of Multi-working voltages gate-last CMOS structure with single gate oxide layer thickness according to the second embodiment of the present invention.

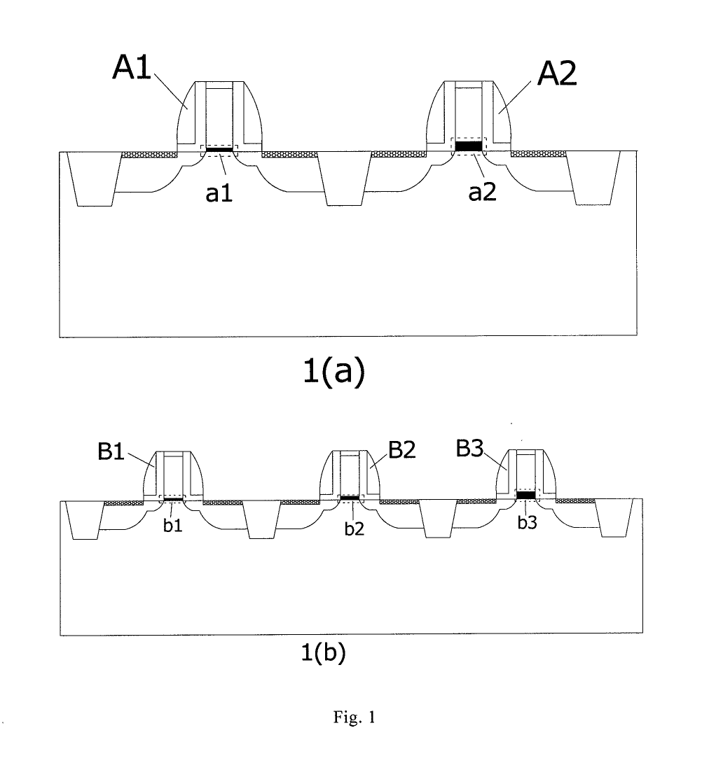

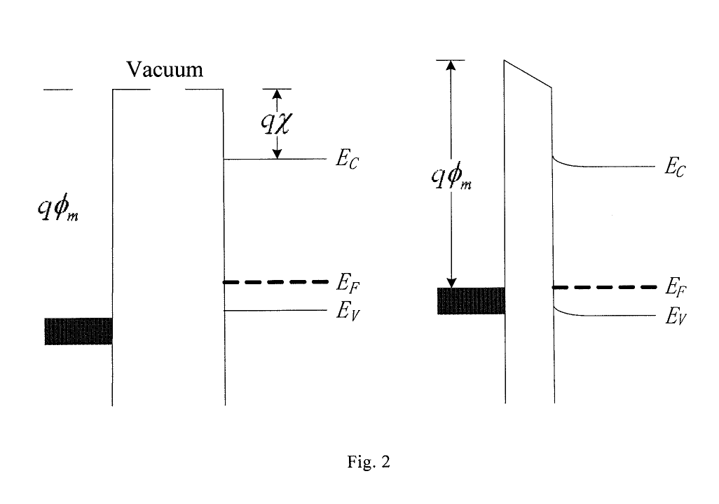

Not all of the reactant is shown in the drawings, and the reactant can be understood in connection with the following embodiments concretely.

### DETAILED EMBODIMENTS OF THE INVENTION

Reference will now be made in detail to the present invention in connection with the accompanying drawings and detailed description. The detailed description set forth herein is just used to explain the present invention, and is not used to limit the protection scope of the present invention.

### First Embodiment

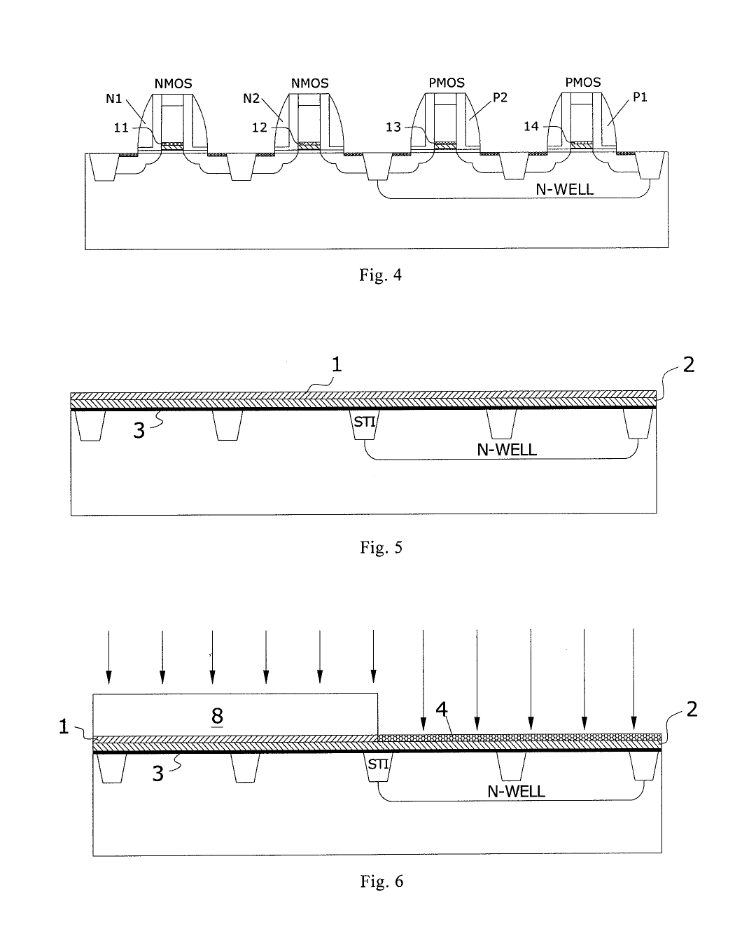

Hereinafter, the first embodiment of the present invention will be described with reference to FIG. 4 to FIG. 9.

According to the first embodiment, the present invention provides a multi-working voltages CMOS device with single gate oxide layer thickness, which comprises a plurality of N-type and P-type MOS transistors, a gate of each of the N-type and P-type MOS transistors comprises a metal oxide dielectric material layer with same thickness; and work functions of the MOS transistors are regulated by implanting ions into the metal oxide dielectric material layers of the MOS transistors; the change of work functions realizes different flat-band voltages under the condition of single dielectric layer (here, i.e., a metal oxide dielectric material layer) thickness, so as to change the working voltages of the MOS devices, thus to realize multi-working voltages CMOS structure under the condition of single dielectric layer thickness.

As shown in FIG. 4, it is a dual-working voltage CMOS device with single gate oxide layer thickness. The CMOS device comprises two NMOS transistors N1 and N2, and two PMOS transistors P1 and P2, wherein, N1 is a NMOS with high working voltage, N2 is a NMOS with low working voltage, P1 is a PMOS with high working voltage, and P2 is a PMOS with low working voltage.

As shown in FIG. 4, on each substrate of four MOS devices N1, N2, P1 and P2, there are a high-k dielectric layer and a metal oxide dielectric material layer on the high-k dielectric layer, and the thicknesses of the metal oxide dielectric material layers are the same.

Both of the metal oxide dielectric material layers 14 and 13 of the P1 and P2 have been implanted with ions which can decrease the work functions of the P-type MOS transistors, so as to decrease the gate work functions of the P-type MOS transistors, thus to increase the absolute values of the working voltages of the P-type MOS transistors; moreover, the metal oxide dielectric material layer 14 of the P1 has been implanted with more ions, which can decrease the gate work functions of the P-type MOS transistors, than the ions implanted into the metal oxide dielectric material layer 13 of the P2, so that the absolute value of the working voltage of the P1 is higher than the absolute value of the working voltage of the P2; thereby, the P1 is a high working voltage P-type MOS transistor, and the P2 is a low working voltage P-type MOS transistor.

Further, both of the metal oxide dielectric material layers 11 and 12 of the N1 and N2 have been implanted with ions which can increase the work functions of the N-type MOS transistors, so as to increase the gate work functions of the N-type MOS transistors, thus to increase the working voltages of the N-type MOS transistors. Moreover, the metal oxide dielectric material layer 11 of the N1 has been implanted with more ions, which can increase the gate work functions of the N-type MOS transistors, than the ions implanted into the metal oxide dielectric material layer 12 of the N2, so that the working voltage of the N1 is higher than the working voltage of the N2; thereby, the N1 is a high working voltage N-type MOS transistor, and the N2 is a low working voltage N-type MOS transistor.

Thus, dual-working voltage CMOS device with single gate oxide layer thickness is realized.

Alternatively, a thin oxide layer is disposed below the high-k dielectric layer of the N1, N2, P1 and P2.

The ions implanted into the metal oxide dielectric material layers on the P-type MOS transistors include lower work function ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element. The ions implanted into the metal oxide dielectric material layers on the N-type MOS transistors include higher work function ions based on B, C, Al, Ti, Cr, Ni, Ge, As, Se, Rh, Pd, Te, Re, Pt, Au, Hg or Po element.

The specific steps for manufacturing the CMOS device are as follows.

In a method for preparing the above dual-working voltage CMOS device with single gate oxide layer thickness, the preparing processes of the CMOS device include the following steps:

Step 1, establishing two N-type MOS transistor preparing regions and two P-type MOS transistor preparing regions on a substrate; and completing the preparation of shallow trenches and shallow trench isolation regions (STI) of the transistors;

Step 2, as shown in FIG. 5, depositing a high-k dielectric layer 2 and a metal oxide dielectric material layer 1 on the N-type MOS transistor preparing regions and the P-type MOS transistor preparing regions of the substrate, the metal oxide dielectric material layer 1 covering the high-k dielectric layer 2;

Step 3, as shown in FIG. 6-FIG. 9,

a. as shown in FIG. 6, covering a photoresist layer 8 on the metal oxide dielectric material layer 1 on the N-type MOS transistor preparing regions by photolithographic process; and implanting ions, which decrease the work functions of the metal oxide dielectric material layer 4, into the metal oxide dielectric material layer 4 on the P-type MOS transistor preparing regions, thus to decrease the work functions of the metal oxide dielectric material layer on the P-type MOS transistor preparing regions, and determine the preparing region of the P-type MOS transistors of the low working voltage CMOS; removing the photoresist layer 8;

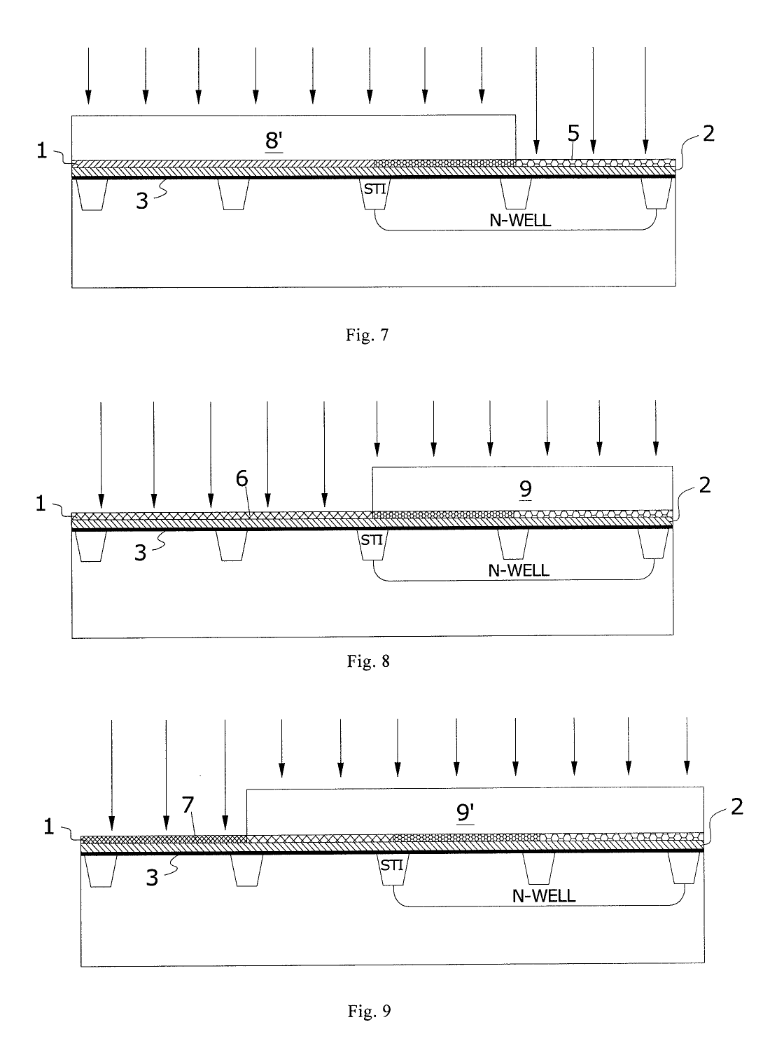

b. as shown in FIG. 7, covering a photoresist layer on the metal oxide dielectric material layer 1 on the P-type and N-type MOS transistor preparing regions, performing photolithography, to remove the photoresist layer which covers on one of the P-type MOS transistor preparing regions, so that the photoresist layer 8′ only covers the metal oxide dielectric material layer on one P-type MOS transistor preparing region; and further implanting ions, which decrease the work function of the metal oxide dielectric material layer 5, into the metal oxide dielectric material layer 5 on another P-type MOS transistor preparing region exposed out of the photoresist layer; thus to further decrease the work function, and determine the P-type MOS transistor preparing region of the high working voltage CMOS; so the work functions of the metal oxide dielectric material layers on the two P-type MOS transistor preparing regions are different from each other, and the gate work functions of the two P-type MOS transistors are different from each other after the preparations of the P-type MOS transistors on the two P-type MOS transistor preparing regions are completed, thus to realize different working voltages, wherein the PMOS with higher absolute value of working voltage is a high working voltage PMOS, and another PMOS is a low working voltage PMOS.

Using the same method, implanting different amount of ions, which can increase the work functions of the metal oxide dielectric material layer, into the metal oxide dielectric material layers on two N-type MOS transistor preparing regions, thus to change the work functions of the metal oxide dielectric material layers on the two N-type MOS transistor preparing regions, and make the work functions of the metal oxide dielectric material layers on the two N-type MOS transistor preparing regions different from each other. The specific processes are as follows:

c. as shown in FIG. 8, covering a photoresist layer 9 on the metal oxide dielectric material layer 4 on the P-type MOS transistor preparing regions by photolithographic process; and implanting ions, which increase the work functions of the metal oxide dielectric material layer 6, into the metal oxide dielectric material layer 6 on the N-type MOS transistor preparing regions, thus to increase the work function of the metal oxide dielectric material layer on the N-type MOS transistors, so as to determine the preparing regions of the N-type MOS transistors of the low working voltage CMOS; removing the photoresist layer 9;

d. as shown in FIG. 9, covering a photoresist layer on the metal oxide dielectric material layer 1 on the P-type and N-type MOS transistor preparing regions, performing photolithography, to remove the photoresist layer which covers on one of the N-type MOS transistor preparing regions, so that the photoresist layer 9′ only covers the metal oxide dielectric material layer on one N-type MOS transistor preparing region; and further implanting ions, which increase the work function of the metal oxide dielectric material layer 7, into the metal oxide dielectric material layer 7 on one N-type MOS transistor preparing region exposed out of the photoresist layer; thus to further increase the work function, so as to determine the N-type MOS transistor preparing region of the high working voltage CMOS; so the work functions of the metal oxide dielectric material layers on the two N-type MOS transistor preparing regions are different from each other, and the gate work functions of the two N-type MOS transistors are different from each other after the preparation of the N-type MOS transistors on the two N-type MOS transistor preparing regions are completed, thus to realize different working voltages, wherein the NMOS with higher working voltage is a high working voltage NMOS, and another NMOS is a low working voltage NMOS.

Step 4, removing the photoresist layer, and completing the subsequent preparation of the N-type and P-type MOS transistors. Thereby, the preparation of the dual-working voltage CMOS device with single gate oxide layer thickness is completed, as shown in FIG. 4.

In the step 1, alternatively, depositing a thin oxide layer 3 on the substrate before the forming of the high-k dielectric layer, the thin oxide layer 3 is disposed below the high-k dielectric layer 2.

The ions implanted into the metal oxide dielectric material layer on the P-type MOS transistor preparing regions include lower work function ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element. The ions implanted into the metal oxide dielectric material layer on the N-type MOS transistor preparing regions include higher work function ions based on B, C, Al, Ti, Cr, Ni, Ge, As, Se, Rh, Pd, Te, Re, Pt, Au, Hg or Po element.

A high working voltage NMOS and a low working voltage NMOS as well as a high working voltage PMOS and a low working voltage PMOS are achieved by the above preparation process, so the preparation achieves a CMOS device with dual-working voltages.

Using the preparing method of the above dual-working voltage CMOS device and analogically, triple-working voltage CMOS device and multi-working voltage CMOS device can be prepared. They all fall into the protection scope of the present invention.

The above embodiment is gate-first CMOS (Gate-first HK/MG CMOS) preparing process, and the present invention is also suitable for gate-last CMOS (Gate-last HK/MG CMOS) preparing process.

### Second Embodiment

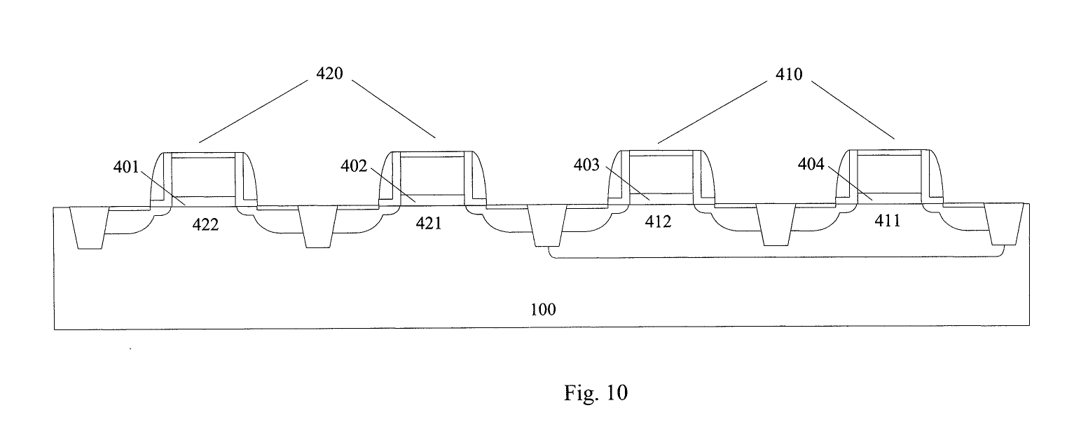

The second embodiment of the present invention is described below with reference to FIG. 10 to FIG. 14.

The first type transistors and second type transistors referred to in the second embodiment of the present invention indicate pairs of PMOS transistors and NMOS transistors, but the first type transistors of the present invention do not indicate PMOS transistors specifically, those skilled in the art can determine the first type transistors and the second type transistors according to specific situations, which will not be described unnecessarily herein.

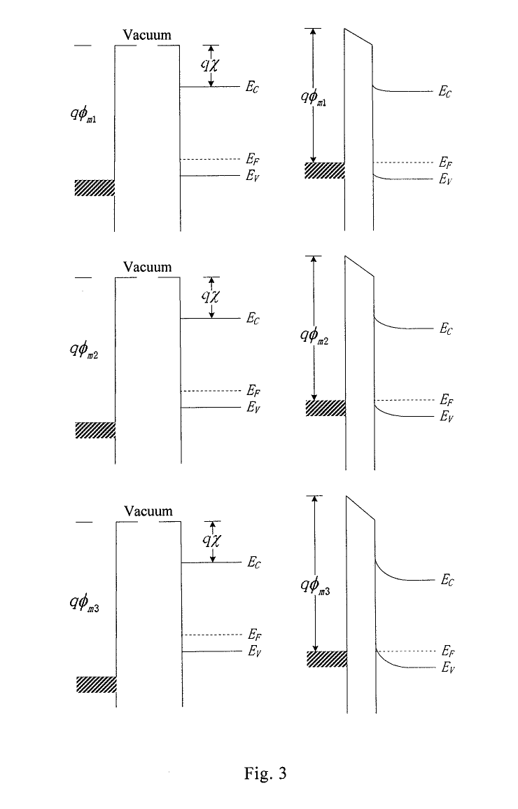

Referring to FIG. 3 again, different flat-band voltages can be realized by changing the work functions of Poly-Silicon or metal layers, so as to realize Multi-working voltages of CMOS under the condition of single dielectric layer thickness.

The second embodiment of the present invention uses this principle to realize multi-working voltages CMOS structure with single gate oxide layer thickness. Please refer to the schematic diagram of multi-working voltages gate-last process CMOS structure with single gate oxide layer thickness shown in FIG. 10. The semiconductor device manufactured by using gate-last preparing processes at least includes a plurality of first type transistors 410 formed on a substrate 100, each of the first type transistors 410 is corresponding to one of a plurality of second type transistors 420 which has a flat-band voltage absolute value similar to that of the first type transistor. In the embodiment as shown in FIG. 10, first transistor 411 and second transistor 412 are first type transistors 410, and third transistor 421 and fourth transistor 422 are second type transistors 420. The first transistor 411 is corresponding to the fourth transistor 422, i.e., the absolute value of the flat-band voltage of the first transistor 411 is similar to that of the fourth transistor 422; the second transistor 412 is corresponding to the third transistor 421, i.e., the absolute value of the flat-band voltage of the second transistor 412 is similar to that of the third transistor 421.

The present embodiment include: gate trenches, included in the plurality of first type transistors and second type transistors respectively (not numbered in FIG. 10); gate oxide layers, formed on the bottom of the respective gate trenches of the plurality of first type transistors and second type transistors, the thicknesses of each of the gate oxide layers are the same; the thicknesses of a first gate oxide layer 401, a second gate oxide layer 402, a third gate oxide layer 403 and a fourth gate oxide layer 404 as shown in the drawings are the same. The gate oxide layers of the plurality of first type transistors are implanted with different amount of first ions respectively (not shown in FIG. 10), such that flat-band voltages of at least two first-type transistors are different from each other; the gate oxide layers of the plurality of second type transistors are implanted with different amount of second ions respectively (not shown in FIG. 10), such that flat-band voltages of at least two second-type transistors are different from each other. As shown in FIG. 10, in the four transistors, the absolute values of the flat-band voltages of two transistors are similar to those of another two transistors respectively, so as to form dual working voltages. Those skilled in the art can understand that more stages of working voltages can be set in the semiconductor devices according to requirements, and the prior art can be combined to realize such changes.

The substrate 100 in the semiconductor device of the present invention can be a bulk silicon, or can be a silicon on insulator to replace the bulk silicon.

In the embodiment as shown in FIG. 10, the first type transistors 410 are PMOS transistors, the second type transistors 420 are NMOS transistors, and the semiconductor device is a CMOS device.

The dual-working voltage semiconductor device with single gate oxide layer thickness is described referring to FIG. 10, wherein, FIG. 10 shows two pairs of CMOS. In at least one pair of first CMOS device, the gate oxide layer of the PMOS transistor (first transistor 411) has a first flat-band voltage by being implanted with first fixed quantity of first ions, the gate oxide layer of the NMOS transistor (fourth transistor 422) has the first flat-band voltage by being implanted with second fixed quantity of second ions, and the absolute values of the flat-band voltages of the first transistor 411 and the fourth transistor 422 are similar. In at least one pair of second CMOS device, the gate oxide layer of the PMOS transistor (second transistor 412) has a second flat-band voltage by being implanted with the first ions having a quantity different from the first fixed quantity, the gate oxide layer of the NMOS transistor (third transistor 421) has the second flat-band voltage by being implanted with the second ions having a quantity different from the second fixed quantity, and the absolute values of the flat-band voltages of the second transistor 412 and the third transistor 421 are similar.

In a preferred embodiment, the first ions are ions having relatively small work functions, so performing ion implanting can decrease gate work function; the second ions are ions having relatively large work functions, so performing ion implanting can increase gate work function, such that the first transistor 411 and the fourth transistor 422 have high working voltages, and the second transistor 412 and the third transistor 421 have low working voltages.

More specifically, the present invention discloses that the following first ions can be chosen concretely: the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; the following second ions can be chosen concretely: the ions based on B, C, Al, Ti, Cr, Ni, Ge, As, Se, Rh, Pd, Te, Re, Pt, Au, Hg or Po element. By combining with the prior art, those skilled in the art may choose other ions to replace the above ions in order to achieve the same purpose.

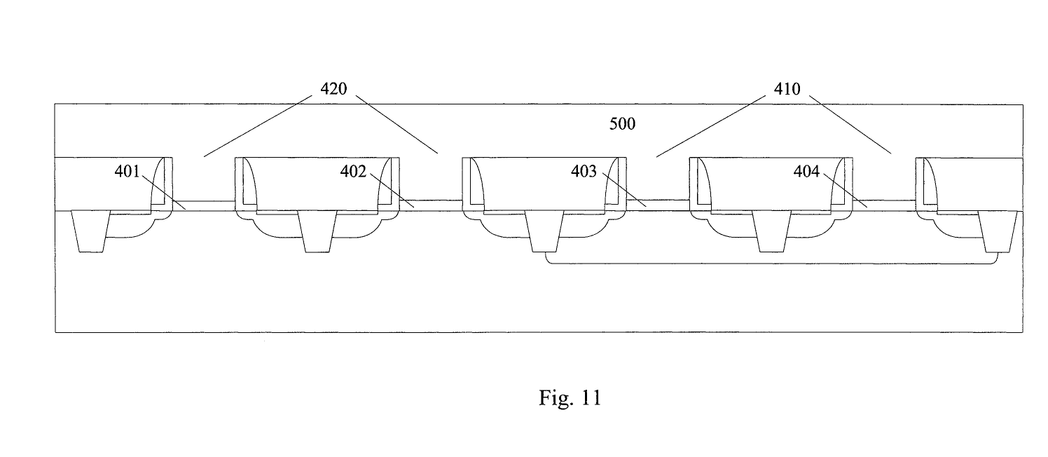

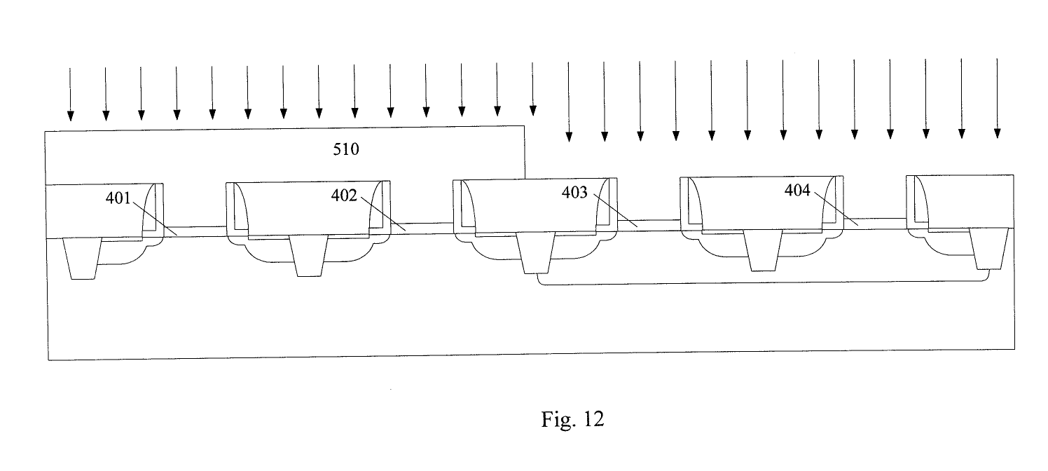

Referring to FIG. 10, and combining FIG. 11 to FIG. 14, a preparing method of multi-working voltages gate-last process semiconductor device with single gate oxide layer thickness according to the present invention will be described below. The preparing method of the present invention is suitable for gate-last preparing processes. As shown in FIG. 11, firstly, forming a plurality of first type transistors 410 and a plurality of second type transistors 420 on a substrate 100, and forming gate trenches included in the plurality of first type transistors and second type transistors respectively (not numbered in FIG. 11), which is characterized in that, performing the following steps in succession:

Depositing to form a gate oxide layer in gate trenches of each of the first type transistors 410 and second type transistors 420, the thicknesses of each of the gate oxide layers being the same. Referring to a first gate oxide layer 401, a second gate oxide layer 402, a third gate oxide layer 403 and a fourth gate oxide layer 404 in FIG. 11, the thicknesses of the four gate oxide layers are the same.

Then, implanting first ions into the gate oxide layers of the first type transistors 410 for multiple times, each implanting at least opening a gate trench of one of the first type transistors, such that the first ions contact the gate oxide layers in the opened gate trenches (referring to FIG. 12), so as to obtain at least two first type transistors 410 having different flat-band voltages.

And performing a following step: implanting second ions into the gate oxide layers of the second type transistors 420 for multiple times, each implanting at least opening a gate trench of one of the second type transistors 420, such that the second ions contact the gate oxide layers in the opened gate trenches, so as to obtain at least two second type transistors 420 having different flat-band voltages, and such that the flat-band voltage absolute value of each of the second type transistors 420 is similar to the flat-band voltage absolute value of a corresponding first type transistor 410.

For further understanding the detailed process of the method according to the present invention, the manufacturing process of the first type transistors 410 is listed below as an example. As shown in FIG. 11, covering a photoresist layer 500 as an implanting barrier layer on the first type transistors 410 and second type transistors 420 firstly; as shown in the drawings, the implanting barrier layer 500 is filled in the gate trenches of the first type transistors 410 and the second type transistors 420, and the function of the implanting barrier layer 500 is to provide a protective film for subsequent ion implanting, so as to prevent the areas which do not need to be ion-implanted from contacting with the implanted ions.

Then, referring to FIG. 12, removing part (not numbered in the drawings) of the implanting barrier layer on several first type transistors 410 by photolithographic process, the rest part 510 of the implanting barrier layer covers on the second type transistors 420 and other first type transistors (not numbered in the drawings). At this time, said several first type transistors 410 are exposed, and the third gate oxide layer 403 and the fourth gate oxide layer 404 disposed in the gate trenches of two first type transistors 410 are exposed.

Then, implanting first ions into the gate oxide layers in the gate trenches of the several first type transistors 410. In FIG. 12, the implanted first ions are in contact with the third gate oxide layer 403 and the fourth gate oxide layer 404 to regulate work functions, but the first ions can not contact the first gate oxide layer 401 and the second gate oxide layer 402 because of the existence of the rest part 510 of the implanting barrier layer. In this step, the third gate oxide layer 403 and the fourth gate oxide layer 404 each have been implanted with a second fixed quantity (implanted once) of first ions.

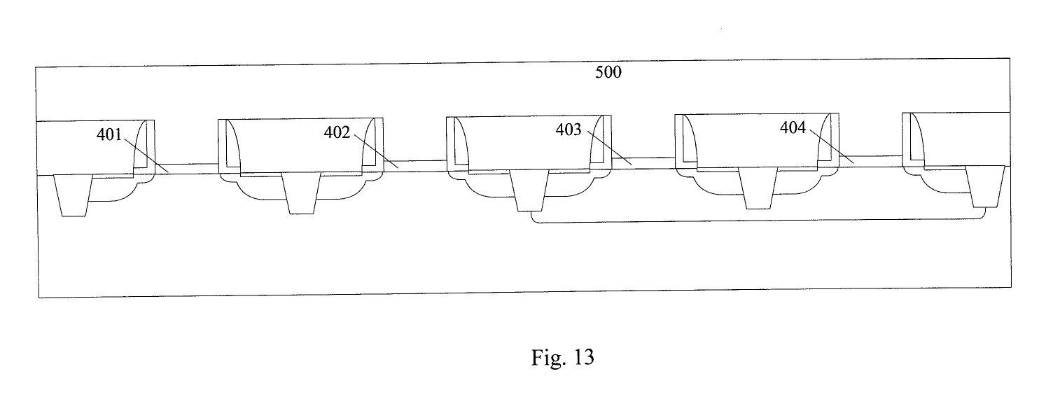

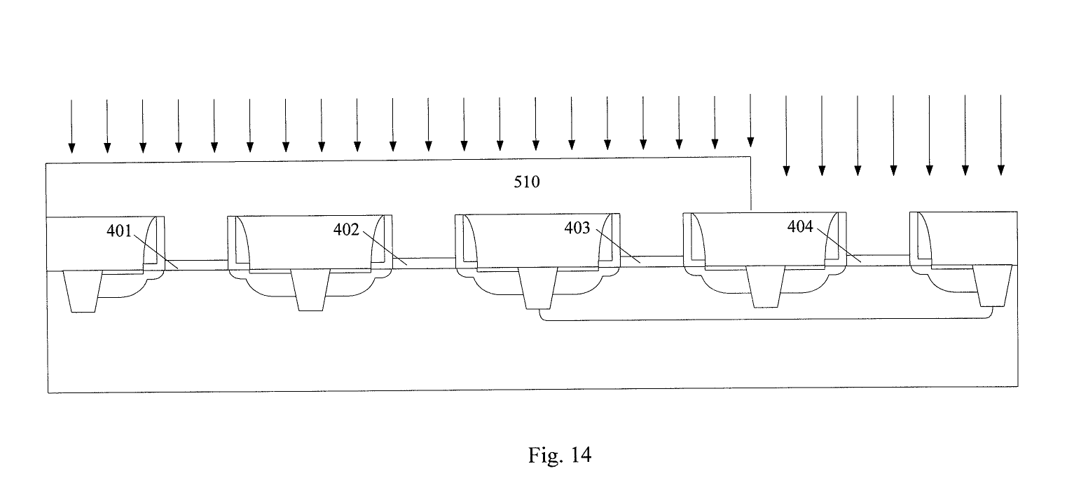

For the purpose of realizing the multi-working voltages of the present invention, it is also necessary to implant the first ions into the gate oxide layer in the gate trench of at least one of the first type transistors 410, so as to obtain different flat-band voltages. Thus, please refer to FIG. 13. A photoresist layer used as an implanting barrier layer 500 (referring to FIG. 11) is covered on the first type transistors 410 and second type transistors 420 over again.

Then, removing part of the implanting barrier layer on at least one first type transistor 410 by photolithographic process, so as to open the gate trench of the at least one first type transistor 410, such that the gate oxide layer in the gate trench of the opened first type transistor 410 is exposed, while remaining part of the implanting barrier layer covered on the second type transistors and other first type transistors. As shown in FIG. 14, the part of the implanting barrier layer on the fourth gate oxide layer 404 is etched and removed.

The first ions are implanted into the exposed gate oxide layers, for example, the first ions are implanted into the fourth gate oxide layer as shown in FIG. 14, other three gate oxide layers in FIG. 14 are covered by the implanting barrier layer, so they can not contact the first ions. At this time, the fourth gate oxide layer 404 is implanted with a first fixed quantity (implanted twice) of first ions.

Although the drawings of the description do not show the manufacturing procedure of the triple-working voltage semiconductor device or more-stage-working voltage semiconductor device, referring to the description to the FIG. 11 to FIG. 14, those skilled in the art should understand that when manufacturing triple-working voltage semiconductor device or more-stage-working voltage semiconductor device, the following steps should be performed in succession:

The above implanting processes of the first ions are repeated until at least two first type transistors 410 having different flat-band voltages are formed. Each implanting makes the accumulated concentration of first ions contained in the gate oxide layer which contacts the first ions improved, such that the work function thereof is further regulated.

At last, after completing the procedure on the side of the first type transistors 410 in needed levels-working voltage semiconductor device, the implanting barrier layer 500 is removed so that the first type transistors 410 and second type transistors 420 are exposed.

Similarly, the steps of implanting second ions into the gate oxide layers of the second type transistors 420 for multiple times can refer to the description to the FIG. 11 to FIG. 14. Those skilled in the art understand that each first type transistor 410 has a corresponding second type transistor 420 which has a flat-band voltage absolute value similar to that of the first type transistor 410. Concretely, because the manufacturing process of the gate oxide layers of the second type transistors 420 is similar to the manufacturing process of the gate oxide layers of the first type transistors 410, the process of implanting second ions into the gate oxide layers of the second type transistors 420 is described briefly as below, and those skilled in the art can achieve the manufacturing process of the gate oxide layers of the second type transistors 420 by combining the description to the manufacturing process of the gate oxide layers of the first type transistors 410.

As shown in FIG. 11, covering a photoresist layer as an implanting barrier layer on the first type transistors 410 and second type transistors 420; removing part of the implanting barrier layer on the second type transistors 420 by photolithographic process;

implanting the second ions into the gate oxide layers in the gate trenches of the exposed second type transistors 420;

covering another photoresist layer as an implanting barrier layer on the second type transistors 420 again;

removing part of the implanting barrier layer on at least one second type transistor 420 by photolithographic process, so as to open the gate trench of the at least one second type transistor 420, such that the gate oxide layer in the gate trench of the opened second type transistor 420 is exposed, while remaining part of the implanting barrier layer covered on other second type transistors 420;

implanting the second ions into the exposed gate oxide layer;

repeating the above implanting procedure of the second ions until at least two second type transistors 420 having different gate oxide layer flat-band voltages are formed; and

removing the implanting barrier layer, such that the first type transistors 410 and second type transistors 420 are exposed.

In a preferred embodiment, according to the method of the present invention, the first type transistors are PMOS transistors, the second type transistors are NMOS transistors, and the semiconductor device is a CMOS device.

Further, the first ions in the method of the present invention are ions having relatively small work functions, so performing ion implanting can decrease gate work function; the second ions are ions having relatively large work functions, so performing ion implanting can increase gate work function.

The present embodiment makes the first transistor 411 and the fourth transistor 422 have high working voltage, and makes the second transistor 412 and the third transistor 421 have low working voltage.

In a specific embodiment, the substrate 100 is a bulk silicon or a silicon on insulator.

More specifically, the present invention discloses that the following first ions can be chosen concretely: the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; the following second ions can be chosen concretely: the ions based on B, C, Al, Ti, Cr, Ni, Ge, As, Se, Rh, Pd, Te, Re, Pt, Au, Hg or Po element. By combing the prior art, those skilled in the art can use other ions to replace the above disclosed ions, so as to achieve the same purpose.

Those skilled in the art should understand that variation examples can be achieved by combining prior art and the above embodiments for those skilled in the art. The variation examples cannot influence the essential content of the present invention, and will not be described unnecessarily herein.

The specific embodiments of the present invention have been described in detail as above, but they are only used as examples, and the present invention is not limited to the above described specific embodiments. For those skilled in the art, any equivalent modifications or substitutions made to the present invention will fall into the scope of the present invention. Therefore, any equivalent modifications or variations without departing from the spirit and scope of the present invention should be covered by the scope of the present invention.

What is claimed is:

1. A multi-working voltages CMOS device with single gate oxide layer thickness, which is characterized in that,
the CMOS device comprises a plurality of N-type MOS transistors and P-type MOS transistors, a gate of each of the N-type MOS transistors and the P-type MOS transistors comprises a high-k dielectric layer and a metal oxide dielectric material layer thereon, and the thicknesses of the metal oxide dielectric material layers are the same,
wherein, the N-type MOS transistors and the P-type MOS transistors have different gate work functions by implanting different amount of ions, which change the work functions of the metal oxide dielectric material layers, into the metal oxide dielectric material layers of the N-type MOS transistors and the P-type MOS transistors, thus to realize a multi-working voltages CMOS structure under the condition of single dielectric layer thickness; and
there are at least two of the P-type MOS transistors with different gate work functions thus to have different working voltages, and there are at least two of the N-type MOS transistors with different gate work functions thus to have different working voltages.

2. The CMOS device as claimed in claim 1, which is characterized in that, the gate work functions of the P-type MOS transistors are decreased and absolute values of the working voltages of the P-type MOS transistors are increased by implanting different amount of ions, which decrease the work functions of the metal oxide dielectric material layers, into the metal oxide dielectric material layers of the P-type MOS transistors; and
the gate work functions of the N-type MOS transistors are increased and the working voltages of the N-type MOS transistors are increased by implanting different amount of ions, which increase the work functions of the metal oxide dielectric material layers, into the metal oxide dielectric material layers of the N-type MOS transistors.

3. The CMOS device as claimed in claim 2, which is characterized in that, the ions implanted into the metal oxide dielectric material layers on the P-type MOS transistors include the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; and the ions implanted into the metal oxide dielectric material layers on the N-type MOS transistors include the ions based on B, C, Al, Ti, Cr, Ni, Ge, As, Se, Rh, Pd, Te, Re, Pt, Au, Hg or Po element.

4. The CMOS device as claimed in claim 1, which is characterized in that, a thin oxide layer is disposed below the high-k dielectric layer of each of the MOS transistors.

5. A method for preparing the multi-working voltages CMOS device with single gate oxide layer thickness as claimed in claim 1, which is characterized in that, the preparing of the CMOS device comprises the following steps:
Step 1, establishing a plurality of N-type MOS transistor preparing regions and a plurality of P-type MOS transistor preparing regions on a substrate; and completing the preparation of shallow trenches and shallow trench isolation regions of a plurality of transistors;
Step 2, depositing a high-k dielectric layer and a metal oxide dielectric material layer on the N-type MOS transistor preparing regions and the P-type MOS transistor preparing regions of the substrate, the metal oxide dielectric material layer covering the high-k dielectric layer;
Step 3, implanting ions, which change work functions of the metal oxide dielectric material layer, into the metal oxide dielectric material layer of the MOS transistor preparing regions respectively by photolithographic process, thus to regulate gate work functions of the completed N-type MOS transistors and P-type MOS transistors, and realize a multi-working voltages CMOS structure under the condition of single dielectric layer thickness,
wherein, implanting different amount of ions, which can decrease the work functions of the metal oxide dielectric material layer, into the metal oxide dielectric material layer on the P-type MOS transistor preparing regions, thus to determine the work functions of the P-type MOS transistors in the multi-working voltages CMOS completed in a subsequent preparation; the specific steps are:
a. covering a photoresist layer on the metal oxide dielectric material layer on the N-type MOS transistor preparing regions by photolithographic process; and implanting ions, which decrease the work functions of the metal oxide dielectric material layer, into the metal oxide dielectric material layer on the P-type MOS transistor preparing regions, thus to decrease the work functions of the metal oxide dielectric material layer on the P-type MOS transistor preparing regions, so as to determine the gate work functions of the P-type MOS transistors in a first stage working voltage CMOS completed in the subsequent preparation; and then removing the photoresist layer;
b. covering a photoresist layer on the metal oxide dielectric material layer on the P-type MOS transistor preparing regions and the N-type MOS transistor preparing regions, performing photolithography, and removing the photoresist layer covered on part of the P-type MOS transistor preparing regions, wherein, the photoresist layer at least covers the metal oxide dielectric material layer on one P-type MOS transistor preparing region; further implanting ions, which decrease the work functions of the metal oxide dielectric material layer, into the metal oxide dielectric material layer on part of the P-type MOS transistor preparing regions exposed out of the photoresist layer, thus to further decrease the work functions of the metal oxide dielectric material layer, so as to determine the gate work functions of the P-type MOS transistors in a second stage working voltage CMOS completed in the subsequent preparation; and
c. repeating the step b, further successively implanting different amount of ions, which can decrease the work functions of the metal oxide dielectric material layer, into the metal oxide dielectric material layer on different P-type MOS transistor preparing regions which have been ion-implanted, so as to change the work functions of the metal oxide dielectric material layer on the P-type MOS transistor preparing regions, thus to determine the gate work functions of the P-type MOS transistors in a third stage or more stage working voltage CMOS completed in the subsequent preparation;
completing the ion implanting into the metal oxide dielectric material layer on each of the P-type MOS transistor preparing regions, and determining the preparing regions of the P-type MOS transistors for each stage in the multi-working voltage CMOS, wherein, there are at least two P-type MOS transistor preparing regions, the work functions of the metal oxide dielectric material layer on the at least two P-type MOS transistor preparing regions being different from each other;
using a method which is the same as the method of implanting different amount of ions, which can decrease the work functions of the metal oxide dielectric material layer, into the metal oxide dielectric material layer on the P-type MOS transistor preparing regions, implanting different amount of ions, which can increase the work functions of the metal oxide dielectric material layer, into the metal oxide dielectric material layer on the N-type MOS transistor preparing regions, thus to determine the gate work functions of the N-type MOS transistors for each stage in the multi-working voltages CMOS completed in the subsequent preparation, and to determine the preparing regions of the N-type MOS transistors for each stage in the multi-working voltages CMOS; and there are at least two N-type MOS transistor preparing regions, the work functions of the metal oxide dielectric material layer on the at least two N-type MOS transistor preparing regions being different from each other; and
Step 4, removing the photoresist layer, and completing the subsequent preparation of the N-type MOS transistors and the P-type MOS transistors.

6. The method as claimed in claim 5, which is characterized in that, in the Step 1, depositing a thin oxide layer on the substrate before the forming of the high-k dielectric layer, the thin oxide layer being disposed below the high-k dielectric layer.

7. The method as claimed in claim 5, which is characterized in that, the ions implanted into the metal oxide dielectric material layer on the P-type MOS transistors include the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; and the ions implanted into the metal oxide dielectric material layer on the N-type MOS transistors include the ions based on B, C, Al, Ti, Cr, Ni, Ge, As, Se, Rh, Pd, Te, Re, Pt, Au, Hg or Po element.

8. A multi-working voltages gate-last process semiconductor device with single gate oxide layer thickness, which is manufactured by using the gate-last preparing process, characterized in that the semiconductor device at least includes:
a plurality of first type transistors formed on a substrate, each of the first type transistors respectively corresponding to a second type transistor which has an absolute value of a flat-band voltage similar to that of the first type transistor;
gate trenches, included in the plurality of first type transistors and the plurality of second type transistors respectively;
gate oxide layers, formed on the bottom of the respective gate trenches of the plurality of first type transistors and the plurality of second type transistors, the thicknesses of each of the gate oxide layers being the same, wherein,
the gate oxide layers of the plurality of first type transistors are implanted with different amount of first ions respectively, such that flat-band voltages of at least two first type transistors are different from each other; and
the gate oxide layers of the plurality of second type transistors are implanted with different amount of second ions respectively, such that flat-band voltages of at least two second type transistors are different from each other.

9. The device as claimed in claim 8, which is characterized in that, the substrate is a bulk silicon or a silicon on insulator.

10. The device as claimed in claim 8, which is characterized in that, the first type transistors are PMOS transistors, the second type transistors are NMOS transistors, and the semiconductor device is a CMOS device.

11. The device as claimed in claim 10, which is characterized in that, the semiconductor device includes:
at least a pair of first CMOS devices, the gate oxide layers of the PMOS transistors of the first CMOS devices have a first flat-band voltage by implanting first fixed quantity first ions, and the gate oxide layers of the NMOS transistors of the first CMOS devices have the first flat-band voltage by implanting second fixed quantity second ions; and
at least a pair of second CMOS devices, the gate oxide layers of the PMOS transistors of the second CMOS devices have a second flat-band voltage by implanting the first ions which have a quantity different from the first fixed quantity, the gate oxide layers of the NMOS transistors of the second CMOS devices have the second flat-band voltage by implanting the second ions which have a quantity different from the second fixed quantity.

12. The device as claimed in claim 11, which is characterized in that, the first ions are ions having relatively small work functions, and the second ions are ions having relatively large work functions.

13. The device as claimed in claim 12, which is characterized in that, the first ions are any of the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; the second ions are any of the ions based on B, C, Al, Ti, Cr, Ni, Ge, As, Se, Rh, Pd, Te, Re, Pt, Au, Hg or Po element.

14. A method for preparing a multi-working voltages gate-last process semiconductor device with single gate oxide layer thickness, which is used for a gate-last preparing process, comprising steps of:
firstly, forming a plurality of first type transistors and a plurality of second type transistors on a substrate, and forming gate trenches included in the plurality of first type transistors and the plurality of second type transistors respectively;
the method is characterized in that, the following steps are performed subsequently:
depositing a gate oxide layer in gate trenches of each of the first type transistors and the second type transistors, the thicknesses of each of the gate oxide layers being the same;
implanting first ions into the gate oxide layers of the first type transistors for multiple times, each implanting at least opening a gate trench of one of the first type transistors, such that the first ions contact the gate oxide layers in the opened gate trenches, so as to obtain at least two first type transistors having different flat-band voltages;
implanting second ions into the gate oxide layers of the second type transistors for multiple times, each implanting at least opening a gate trench of one of the second type transistors, such that the second ions contact the gate oxide layers in the opened gate trenches, so as to obtain at least two second type transistors having different flat-band voltages, and such that a flat-band voltage absolute value of each second type transistor is similar to that of a corresponding first type transistor.

15. The method as claimed in claim 14, which is characterized in that, the step of implanting first ions into the gate oxide layers of the first type transistors for multiple times includes:
covering an implanting barrier layer on the first type transistors and the second type transistors;
removing part of the implanting barrier layer on the first type transistors;
implanting first ions into the gate oxide layers in the gate trenches of the first type transistors;
removing the implanting barrier layer, and then covering another implanting barrier layer on the first type transistors and the second type transistors;
removing part of the implanting barrier layer on at least one first type transistor to open the gate trench of the at least one first type transistor, such that the gate oxide layer in the gate trench of the opened first type transistor is exposed, and remaining part of the implanting barrier layer covered on the second type transistors and other first type transistors;
implanting the first ions into the exposed gate oxide layer;
repeating the aforesaid implanting procedure of the first ions until at least two first type transistors having different flat-band voltages of the gate oxide layers are formed; and
removing the implanting barrier layer, such that the first type transistors and second type transistors are exposed.

16. The method as claimed in claim 14, which is characterized in that, the step of implanting second ions into the gate oxide layers of the second type transistors for multiple times includes:
covering an implanting barrier layer on the first type transistors and the second type transistors;
removing part of the implanting barrier layer on the second type transistors;
implanting second ions into the gate oxide layers in the gate trenches of the second type transistors;
removing the implanting barrier layer, and then covering another implanting barrier layer on the first type transistors and the second type transistors;
removing part of the implanting barrier layer on at least one second type transistor to open the gate trench of the at least one second type transistor, such that the gate oxide layer in the gate trench of the opened second type transistor is exposed, and remaining part of the implanting barrier layer covered on the first type transistors and other second type transistors;
implanting the second ions into the exposed gate oxide layer;
repeating the aforesaid implanting procedure of the second ions until at least two second type transistors having different flat-band voltages of the gate oxide layers are formed; and
removing the implanting barrier layer, such that the first type transistors and second type transistors are exposed.

17. The method as claimed in claim 14, which is characterized in that, the first type transistors are PMOS transistors, the second type transistors are NMOS transistors, and the semiconductor device is a CMOS device.

18. The method as claimed in claim 17, which is characterized in that, the first ions are ions having relatively small work functions, the second ions are ions having relatively large work functions.

19. The method as claimed in claim 14, which is characterized in that, the substrate is a bulk silicon or a silicon on insulator.

20. The method as claimed in claim 18, which is characterized in that, the first ions are any of the ions based on Li, Mg, Ca, Sc, Mn, Ga, Rb, Sr, Y, Zr, Nb, In, Cs, Ba, La, Nd, Pr, Pm, Gd, Dy, Ho, Tb, Yb, Tm, Er, Lu, Hf, Ta, Pb, Fr, Ra, Ac or Th element; the second ions are any of the ions based on B, C, Al, Ti, Cr, Ni, Ge, As, Se, Rh, Pd, Te, Re, Pt, Au, Hg or Po element.
